(19) United States
(12) Patent Application Publication
(10) Pub. No.: US 2023/0382722 A1
(43) Pub. Date: Nov. 30, 2023

(54) MEMS Package and Method for Encapsulating an MEMS Structure

(71) Applicant: Fraunhofer-Gesellschaft zur Förderung der angewandten Forschung e.V., München (DE)

(72) Inventors: Frank SENGER, Itzehoe (DE); Shanshan GU-STOPPEL, Itzehoe (DE); Erdem YARAR, Itzehoe (DE); Gunnar WILLE, Itzehoe (DE)

(21) Appl. No.: 18/366,201

(22) Filed: Aug. 7, 2023

Related U.S. Application Data
(63) Continuation of application No. PCT/EP2022/052854, filed on Feb. 7, 2022.

(30) Foreign Application Priority Data
Feb. 8, 2021 (DE) 10 2021 201 151.9

(51) Int. Cl. B81C 1/00; B81B 7/00

(52) U.S. Cl. CPC B81C 1/00317; B81B 7/0041; B81C 2203/0118; B81C 2201/0123; B81B 2201/032; B81B 2201/042; B81B 2203/0163

(57) ABSTRACT

A method for encapsulating an MEMS structure in a stack structure includes providing a functional wafer structure including at least partly the MEMS structure. The method includes arranging the functional wafer structure and a glass wafer in the stack structure and along a stacking direction and is performed such that a cavity, in which at least part of the MEMS structure is arranged, is closed on one side along the stacking direction by the glass wafer and such that a spacing structure is arranged between the part of the MEMS structure and the glass wafer in the stack structure to provide a spacing between the part of the MEMS structure and the glass wafer along the stacking direction, such that the spacing structure encloses part of the cavity.

### CROSS-REFERENCE TO RELATED APPLICATIONS

This application is a continuation of copending International Application No. PCT/EP2022/052854, filed Feb. 7, 2022, which is incorporated herein by reference in its entirety, and additionally claims priority from German Application No. 10 2021 201 151.9, filed Feb. 8, 2021, which is also incorporated herein by reference in its entirety.

The present invention relates to a method for encapsulating an MEMS structure, such as with a moveable element, such as in quasi-static MEMS components such as MEMS vector scanners. Further, the present invention relates to an MEMS package. Further, the present invention relates to arranging a wafer stack for hermetic encapsulation with defined internal pressure for a quasi-static MEMS component.

### BACKGROUND OF THE INVENTION

MEMS vector scanners are encapsulated with a hybrid assembly, such as by using a ceramic housing.

For the purpose of high mechanical efficiency, MEMS vector scanners have complex structures, such as a 3D design, wherein the actuators and the mirror plate are located on different levels. This 3D structure is frequently used, but is inconvenient for encapsulation and complicates the same.

For adjusting their behavior, MEMS vector scanners are encapsulated in a hybrid assembly and hermetically sealed. Hermetic encapsulation of the vector scanners with a 3D structure where the actuators and mirror plates are located on different heights/levels allows the protective effect for MEMS components, but the MEMS component still suffers from influences due to external interferences, such as particles. Degassing due to the different production environments and methods and the needed transport between the production environments is inconvenient. MEMS components are normally produced in a clean room and the following hybrid assembly is realized in the laboratory field by means of an adhesive.

A method for producing an MEMS package or for encapsulating an MEMS structure and an MEMS package that prevents the above disadvantages and can still be produced efficiently and with few errors would be desirable.

### SUMMARY

According to an embodiment, a method for encapsulating an MEMS structure in a stack structure may have the steps of: providing a functional wafer structure including at least partly the MEMS structure; arranging the functional wafer structure and a glass wafer in the stack structure and along a stacking direction to each other; such that a cavity in which at least a part of the MEMS structure is arranged is closed on one side along the stacking direction by the glass wafer; and such that a spacing structure is arranged between the part of the MEMS structure and the glass wafer in the stack structure to provide a spacing between the part of the MEMS structure and the glass wafer along the stacking direction; such that the spacing structure encloses part of the cavity, wherein the spacing structure is formed of the functional wafer structure by means of local selective removal of the wafer structure.

According to another embodiment, a method for encapsulating an MEMS structure in a stack structure may have the steps of: providing a stack structure with a plurality of MEMS areas, such that each MEMS area includes an MEMS structure that is arranged at least partly in an MEMS cavity; such that the stack structure includes a spacing structure enclosing each of the cavities of the MEMS areas at least partly and providing a spacing to the MEMS structure along a stacking direction, wherein the spacing structure is formed from the functional wafer structure by means of local selective removal of the wafer structure; and arranging a glass wafer on the spacing structure along the stacking direction by performing a wafer bonding process, such that the cavities on one side of the spacing structure are hermetically sealed by means of the glass wafer.

According to another embodiment, an MEMS package may have: a stack structure including several layers stacked along a stacking direction; and including a functional layer structure including an MEMS structure; wherein the MEMS structure is at least partly arranged in a cavity; and the cavity forms part of the stack structure; wherein the cavity is limited on one side along the stacking direction by a glass layer, which is spaced apart from the MEMS structure along the stacking direction by a spacing layer, wherein the spacing structure is formed from the functional wafer structure by means of local selective removal of the wafer structure.

It is a core idea of the present invention to provide, for encapsulating an MEMS structure, spacing structure between a part of an MEMS structure and a lid implemented by means of a glass wafer. This enables low processing requirements at the glass wafer, simple positioning of the spacing structure with respect to the MEMS structure and still production on wafer level, such that encapsulating with low susceptibility to errors is enabled in an efficient manner.

According to an embodiment, a method for encapsulating an MEMS structure in a stack structure includes providing a functional wafer structure that at least partly includes an MEMS structure. For encapsulating the MEMS structure in a stack structure, further, the functional wafer structure and a glass wafer are arranged in the stack structure and along a stacking direction to each other. The method is performed such that a cavity in which at least a part of the MEMS structure is arranged is closed on one side along the stacking direction by the glass wafer and such that a spacing structure is arranged between the part of the MEMS structure and the glass wafer in the stack structure to provide a spacing between the part of the MEMS structure and the glass wafer along the stacking direction, such that the spacing structure encloses a part of the cavity.

According to an embodiment, a method for encapsulating an MEMS structure in a stack structure includes providing a stack structure with a plurality of MEMS areas, such that each MEMS area comprises an MEMS structure that is arranged at least partly in an MEMS cavity, such that the stack structure comprises a spacing structure enclosing each of the cavities of the MEMS areas at least partly and providing a spacing to the MEMS structure. Further, the method includes arranging a glass wafer on the spacing structure by performing a wafer bonding process, such that the cavities on one side of the spacing structure are hermetically sealed by means of the glass wafer. Here, it is advantageous that by adjusting the spacing by the spacing structure, a complex structure of the glass wafer can be omitted and the same can be used in a simple and efficient manner with few errors already on the wafer level for encapsulating the MEMS structure.

According to an embodiment, an MEMS package includes a stack structure that includes several layers stacked along a stacking direction and comprises a functional layer structure that includes an MEMS structure. The MEMS structure is at least partly arranged in a cavity, wherein the cavity forms part of the stack structure. The cavity is limited on one side along the stacking direction by a glass layer that is spaced apart from the MEMS structure along the stacking direction by a spacing layer.

### BRIEF DESCRIPTION OF THE DRAWINGS

Embodiments of the present invention will be detailed subsequently referring to the appended drawings, in which:

FIG. 1 is a schematic flow diagram of a method according to an embodiment;

FIG. 2 is a schematic flow diagram of a method according to an embodiment that can implement, for example, at least part of a step of the method of FIG. 1;

FIG. 3 is a schematic flow diagram of a further method according to an embodiment which can alternatively or additionally perform at least part of a step of the method of FIG. 1 and can be performed, for example, alternatively or in addition to the method of FIG. 2;

FIG. 4 is a schematic side sectional view of an exemplary functional wafer in the context of embodiments described herein;

FIG. 5 is a schematic side sectional view of a further functional wafer structure according to an embodiment;

FIG. 6 is a schematic side sectional view of a stack structure that can be obtained by joining the functional wafer structures of FIG. 4 and FIG. 5;

FIG. 7 is a schematic side sectional view of a wafer structure according to an embodiment that can be used, for example as bottom or lid wafers;

FIG. 8 is a schematic side sectional view of a stack structure according to an embodiment that can be obtained from a processed version of the stack structure of FIG. 6 and the wafer structure of FIG. 7;

FIG. 9 is a schematic side sectional view of a stack structure according to an embodiment that can be obtained by combining the stack structure of FIG. 8 with a glass wafer;

FIG. 10 is a schematic side sectional view of a stack structure according to an embodiment that can be obtained by further processing the stack structure of FIG. 9.

### DETAILED DESCRIPTION OF THE INVENTION

Before embodiments of the present invention will be discussed in more detail based on the drawings it should be noted that identical, functionally equal or equal elements, objects and/or structures in the different figures are provided with the same reference numbers, such that the description of the these elements illustrated in the different embodiments is interchangeable or inter-applicable.

Embodiments described below will be described in the context of a plurality of details. However, embodiments can also be implemented without these detailed features. Further, embodiments are described by using block diagrams instead of a detailed illustration for clarity purposes. Further, details and/or features of individual embodiments can easily be combined as long as it is not explicitly described to the contrary.

The following embodiments relate to an encapsulation of an MEMS structure. Here, an MEMS vector scanner is considered as exemplary MEMS structure, i.e. a micro-electromechanical system (MEMS) having an optically reflective area that is deflected by using actuator technology. An optical source for this can be part of the MEMS, however, this is not needed for considering the present invention. An exemplary light source is, for example, a laser or another electromagnetic radiation source in the visible or nonvisible wavelength range. Although vector scanners are normally operated in a non-resonant manner, the present invention is not limited thereto. Rather, other MEMS, for example operated in a resonant manner can be encapsulated with the method described herein and/or also MEMS comprising other moveable elements or possibly no moveable elements can be encapsulated. Encapsulation of MEMS structures can also be relevant for other areas where, for example, a reference atmosphere is to be encapsulated with respect to external influences, wherein here, for example, optical areas or areas for measuring a change of the reference atmosphere can be considered.

The following embodiments relate to an encapsulation of an MEMS structure. The same can have one or several layers and can comprise semiconductor materials, such as silicon-based potassium arsenite or the same. However, embodiments are not limited to inorganic semiconductors but can also be applied to organic, such as metalorganic semiconductors.

MEMS structures can comprise semiconductor materials having electrical insulating characteristics under the influence of further processing steps, such as silicon oxide or silicon nitride that are formed in an electrically conductive manner in areas, such as by doping, which are functionalized by arranging additional layers, wherein local selective removal of layers can also be considered.

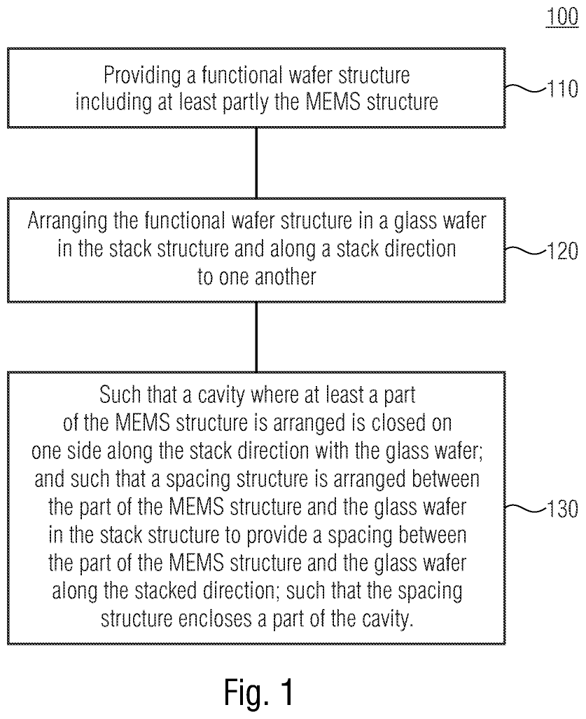

FIG. 1 shows a schematic flow diagram of a method 100 according to an embodiment. The method 100 can be used for encapsulating an MEMS structure in a stack structure, i.e. the MEMS structure is arranged in the stack structure. The method 100 includes a step 110 where a functional wafer structure is provided, which at least partly includes the MEMS structure. Here, functional can mean an electric function, i.e. electrical conductivity and/or insulation and/or mechanical movement. Here, the wafer structure can include one or several wafers, which will be discussed in more detail below.

Step 120 includes arranging the functional wafer structure and a glass wafer in the stack structure and along a stacking direction to each other, which means the glass wafer and the functional wafer structure are arranged together in the stack structure. For example, the glass wafer can be bonded by means of wafer bonding to the layers of the wafer structure or an already formed stack structure with the wafer structure. The method 100 is performed such that a cavity in which at least part of the MEMS structure is arranged, is closed on one side along the stacking direction with the glass wafer, for example in a hermetically sealed manner and such that a spacing structure is arranged between the part of the MEMS structure and glass wafer in the stack structure to provide a spacing between the part of the MEMS structure and the glass wafer along the stacking direction, such that the spacing structure encloses a part of the cavity. This is illustrated in step 130. At least part of step 130 can be performed as a separate step of method 100 or as part of other steps, for example step 120. A result of the method 100 can be an MEMS structure comprising the spacing structure on at least one side along the stacking direction, which does not exclude intermediate layers. The spacing structure can have one or several layers and can provide part of the structure for the glass wafer enclosing the cavity. Here, for example, the spacing structure can be arranged on the stack structure first, whereupon the glass wafer is arranged subsequently. Alternatively, it is also possible that the spacing structure is arranged completely or partly on the glass wafer first and the entire compound of such a lid is then arranged on the stack structure.

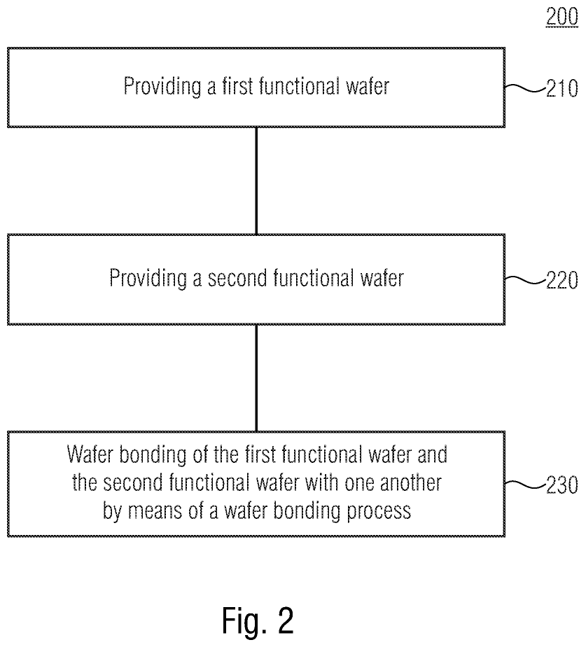

FIG. 2 shows a schematic flow diagram of a method 200, which can implement, for example, at least part of the step 110 of the method 100. Step 210 includes providing a first functional wafer. Step 220 includes providing a second functional wafer. In step 230, wafer bonding of the first functional wafer and the second functional wafer with each other can be performed by means of a wafer bonding process.

The method 200 is a possible implementation of step 110. Multilayered functional wafer structures can be produced or provided by means of the method 200. Alternatively or additionally, step 110 can also comprise etching out successively grown up layers or the same from an entire layer sequence. Alternatively or additionally, step 110 can also be performed by supplying the functional wafer structure.

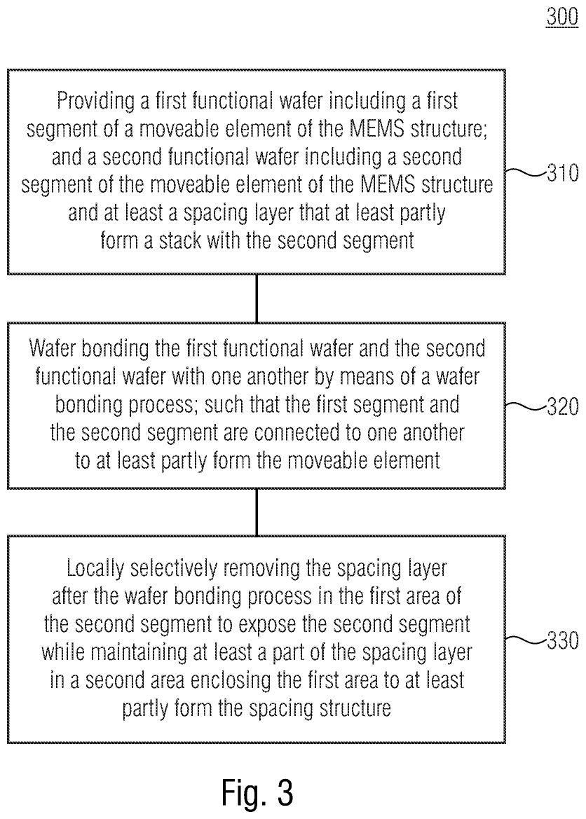

FIG. 3 shows a schematic flow diagram of a method 300 according to an embodiment which can alternatively or additionally perform at least part of step 110 and can be performed, for example, alternatively or additionally to the method 200 or can at least implement the same in more detail.

In step 310, a first functional wafer can be provided, which includes a first segment of a moveable element of the MEMS structure. Further, a second functional wafer can be provided, which includes a second segment of the moveable element of the MEMS structure and at least one spacing layer that at least partly forms a stack together with the second segment. Step 310 can provide, for example, steps 210 and 220.

In step 320, wafer bonding the first functional wafer and the second functional wafer with each other and by means of a wafer bonding process can take place. Thereby, the first segment and the second segment can be connected to each other to at least partly form the moveable element of the MEMS structure. Step 320 can at least partly provide step 230.

In step 330, local selective removal of the spacing layer after the wafer bonding process and in a first area of the second segmenting can take place to expose the second segment. Here, local selective removal can be performed such that the spacing structure is at least partly formed by maintaining at least part of the spacing layer in the second area enclosing the first area. This means a segment of the moveable structure can be removed from the spacing layer and at the same time the spacing layer can be obtained, for example when method 300 is performed.

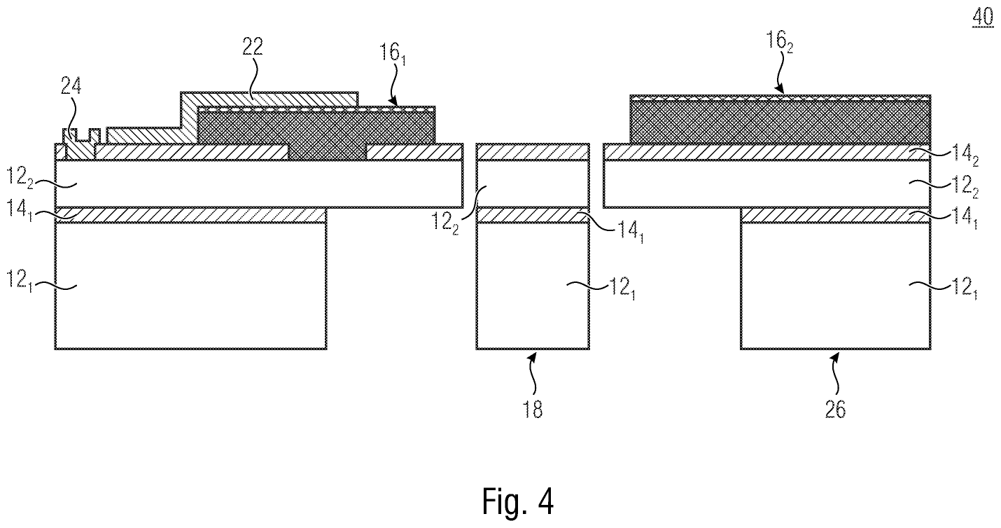

FIG. 4 shows a schematic side sectional view of an exemplary functional wafer in the context of embodiments described herein. The wafer structure 40 can comprise one or several substrate layers 12₁, 12₂ and/or further substrate layers. An intermediate layer 141 can be arranged between substrate layers 12₁, 12₂. The same can comprise, for example, an oxide layer and/or a nitride layer, can include a single layer or can also have a multilayered compound system. A function of the intermediate layer 141 can include, for example, connecting the substrate layers 12₁, 12₂, an electric conductivity or electric insulation can be provided, but also a different function can be provided, for example implementing an etching stop layer or the same.

Optionally, the wafer structure 40 can comprise one, two, or several actuator structures 16₁ and 16₁ that are possibly configured to deflect a deflectable area 18 in a later MEMS. The actuator structures 16₁ and 16₂ can include, for example, piezoelectric functional layers, thermomechanical or thermoelectrical functional layers, can comprise magneto-active materials or can provide any other actuator principle. Alternatively or additionally, the sensory materials can also be located at the location of the actuator structures 16₁ and/or 16₂ or at other locations, such as for evaluating a movement of the deflectable area 18. Here, it is possible but not needed that the deflectable area 18 is implemented at all.

For electrically contacting an active or sensory functional material, one or several electrical conductor structures 22 can be arranged, which can be electrically controlled, for example via electrical contacting 24. This means the electrical contacting 24 and the electric conductor 22 can be electrically connected in an interface layer of the wafer structure 14 that is not illustrated. Also, the deflectable area 18 and an external area 24 of the wafer structure 40 can be connected to one another via one or several mechanical elements, for example spring elements, to suspend or support the deflectable area 18 with respect to the external area 24.

Intermediate layers, for example an electrically insulating intermediate layer 142 can be arranged between the elements 16₁ and 16₂ exemplarily formed as piezoelectric actuators on the one hand and further substrate layers 12₁ and/or 12₂.

In other words, FIG. 4 shows an illustration of a first functional wafer, in the case of an MEMS vector scanner, for example, the actuator wafer. In FIG. 4, at least some of the functional parts of the device are illustrated, for example to realize the desired movement.

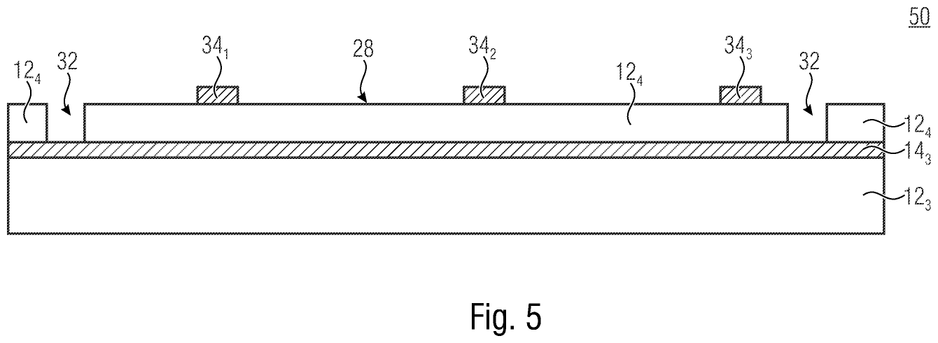

FIG. 5 shows a schematic side sectional view of a functional wafer structure 50 according to an embodiment. The functional wafer structure 50 can comprise one or several substrate layers 12₃ and 12₄, wherein a lower or higher number of substrate layers is also possible. Like the substrate layers 12₁ and 12₂ of FIG. 4, the substrate layers 12₃, and 12₄ can have the same or differing materials.

One or several of the substrate layers 12₃ and 12₄ can be structured into partial areas as illustrated exemplarily for the substrate layer 12₄, which is separated by an intermediate layer 14₃ from the substrate layer 12₃ or provides a mechanical connection between these layers. The substrate layer 12₄ can provide by itself or in cooperation with further layers, such as the layer 14₃ or another layer, a function of the MMS layer, for example the function of a mirror area. Within the embodiment of production or encapsulation of an MEMS vector scanner, the functional wafer structure 50 can, for example, be considered as a mirror wafer. In other words, FIG. 5 shows a second functional wafer, in the case of an MEMS vector scanner the mirror wafer. Depending on the type of MEMS component, a functional wafer, two functional wafers or possibly a higher number can be hermetically encapsulated by the methods described herein.

By providing or generating the functional wafer structure 40, for example step 110 or 120 can be performed. By producing, generating or providing the functional wafer structure 50, for example the other one of steps 110 and 120 or 210 and 220 can be performed.

With reference to the method 300, step 310 can be performed, for example such that the wafer structure 40 is provided as first functional wafer and the wafer structure 50 as second functional wafer. The deflectable area 18 of the functional wafer structure 40 can include, for example, a moveable element of the MEMS structure or provide the same or form at least part thereof. On the other hand, part of the layer 12₄ of the functional wafer structure 50 can provide a second segment of the moveable element of the MEMS structure. As will be explained below, a spacing layer can be formed out of the layer 12₃, which can be used in the later MEMS.

The substrate layer 12₄ can comprise, for example, an inner area 28, such as by introducing one or several trenches 32 into the layer. Alternatively or additionally, one or several bonds 34₁, 34₂ and/or 34₃ can be arranged that can provide a mechanical connection to an adjacent layer during a later connecting process, such as the wafer bonding process. For this, for example, a silicon oxide or a silicon nitride material can be used. Alternatively, any other material for wafer bonding can be arranged. It is possible but not needed that the bonds 34₁ to 34₃ are completely arranged on the functional wafer structure 50, the same can alternatively or additionally also be arranged completely or partly on the functional wafer structure 40.

This means the functional wafer structures 40 and/or 50 can also be implemented in any other manner.

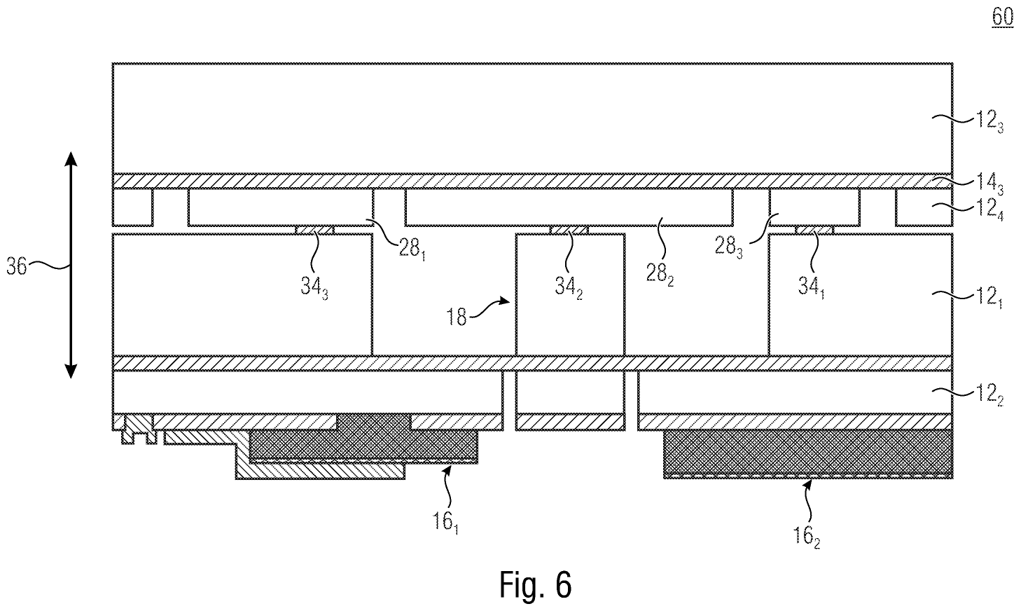

FIG. 6 shows a schematic side sectional view of a stack structure 60 that can be obtained by joining the functional wafer structures 40 and 50. By means of a wafer bonding process, for example in step 320, step 230 and/or step 110 as a whole. Thereby, the substrate layers 12₁, 12₂, 12₃ and 12₄ can be a common part of the stack structure 60 and can be arranged along a stacking direction 36.

Further, the inner area 28 of the functional wafer structure 50 is structured into several partial segments 28₁, 28₂ and 28₃. Together with the deflectable area 18, the segment 28₂ can later form at least part of a deflectable mirror.

In other words, in the case of a vector scanner, the mirror wafer 50 can be bonded together with the actuator wafer 40. Thus, the functional part can consist of one or two wafers.

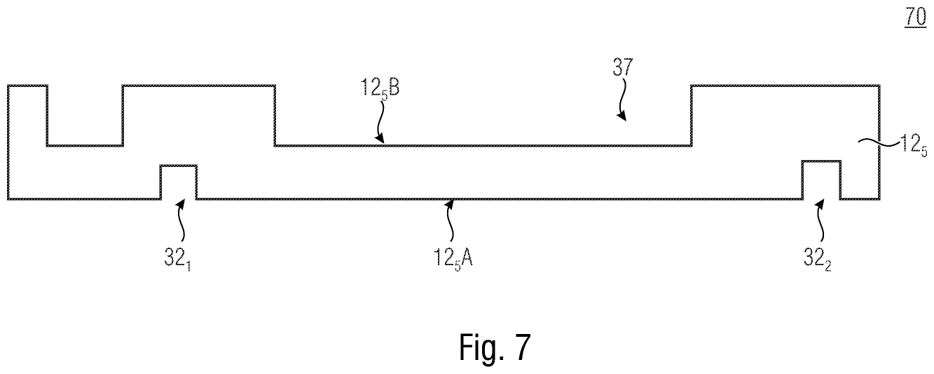

FIG. 7 shows a schematic side sectional view of a wafer structure 70 according to an embodiment. The same includes, exemplarily, a single substrate layer 12₅, wherein alternatively a higher number of substrate layers can be arranged that can be connected integrally or by means of intermediate layers. The substrate layer 12₅ can be formed in a planar manner on one or both opposite main sides or can be structured on one or on both main sides. The wafer structure 70 can be arranged in the stack 60 to form part of the stack structure as limiting wafer structure.

In that way, trenches 32₁ and 32₃ arranged on a main side 12₅A can be introduced as indicators for a later dicing or singulating of wafer segments. Also, one or several depressions or recesses can be arranged on an opposite main side 12₅B. A recess 37 on the side 12₅B can be adapted, for example, to a movement of one or several segments of a later MEMS structure. Here, the recess is introduced into a single layer or semiconductor layer, i.e., side walls of the recess 37 are arranged in the same layer as the bottom area.

In other words, FIG. 7 shows a bottom wafer that can be used when a cavity is provided. The bottom of the cavity can represent a bottom limit of the hermetic encapsulation.

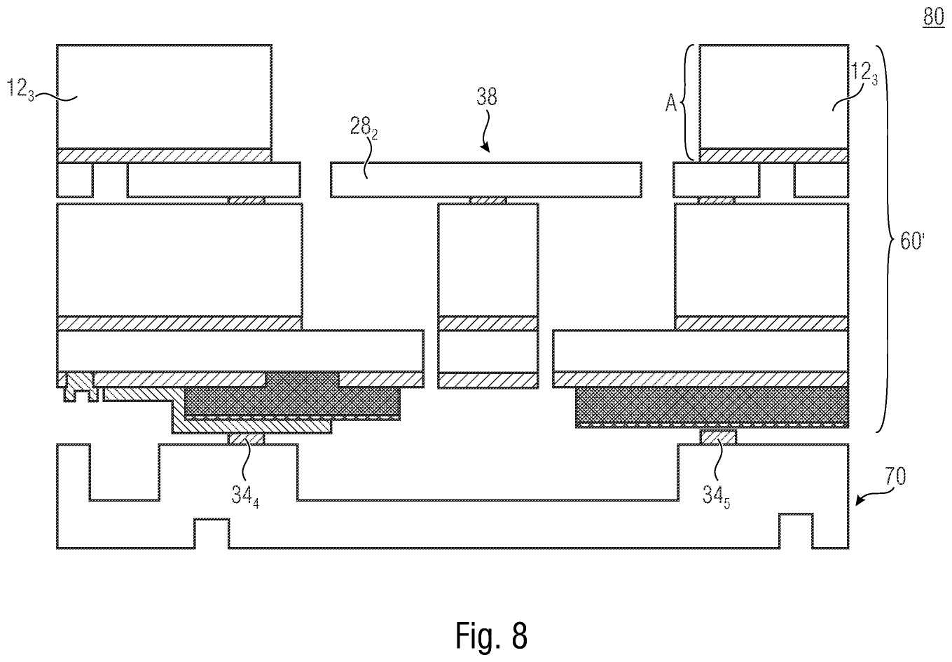

FIG. 8 shows a schematic side sectional view of a stack structure 18 according to an embodiment that can be obtained from a processed version 60′ of the stack structure 60 of FIG. 6 and the wafer structure 70 of FIG. 7, for example by connecting the stack structure 60′ or 60 by means of a connecting area 34₄ and/or 34₅, for example by a wafer bonding process. For example, the areas 34₄ and 34₅ can form a circumferential area, such that there is a hermetically sealed connection between the stack structure 60 or 60′ and the wafer structure 70. This wafer bonding process can take place in the same processing environment or the same process chamber as the connection of the wafer structures 40 and 50.

With respect to the stack structure 60, the stack structure 60′ can be further processed. While, for example, by connecting the wafer structures 40 and 50, for example by performing step 320, the segments “mirror element” and “movable pole” are joined, a moveable element 38 of the stack structure 80 can be exposed by local selective removing of the substrate layer 12₃, for example opposite to the area 28₂. In external areas, the substrate layer 12₃ can remain and, for example, act as spacing layer to adjust the spacing A to the movable element 38, in particular for further additional layers. The layer 12₃ can adjust, as a spacing structure, a spacing A between the MEMS structure or components thereof and a later lid layer and at least partly provide the same. The spacing A can be adapted to an intended volume of a later cavity and/or a motion amplitude of movable components of the MEMS structure.

In other words, according to FIG. 8 with respect to FIGS. 6 and 7, the stack of the functional wafers is again bonded together with the bottom wafer. Here, it is possible to obtain or maintain a specific spacing towards the top to the later lid wafer by the functional wafer.

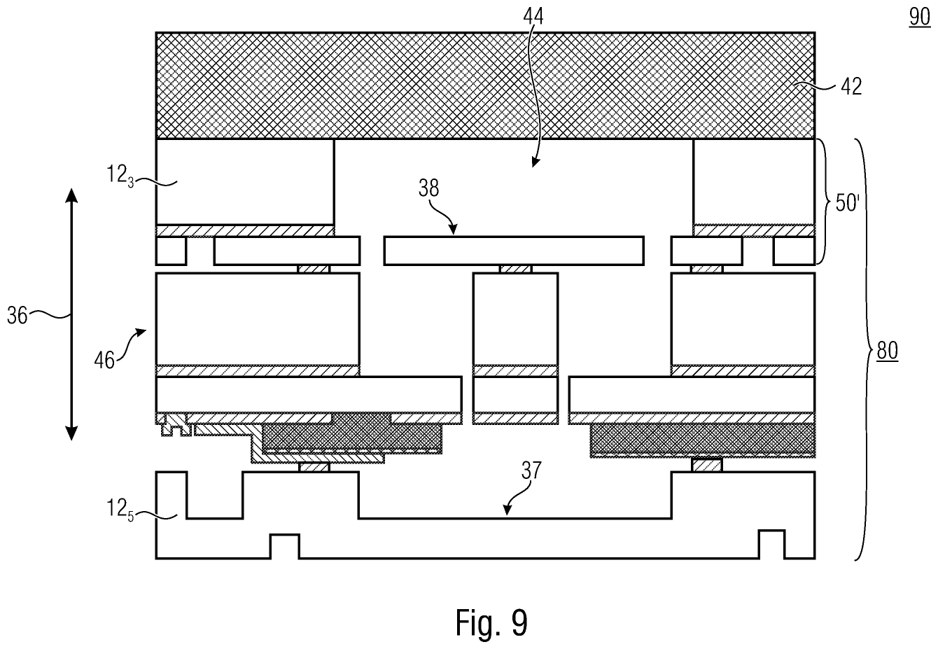

FIG. 9 shows a schematic side sectional view of a stack structure 90 according to an embodiment that can be obtained by combining the stack structure 80 of FIG. 8 with a glass wafer 42. The same can be arranged, for example, as lid or as part thereof at the stack structure 80, such that a cavity 44 where the movable element 30 is arranged in a moveable manner is hermitically sealed, on the one hand, by the substrate layers 12₅ or the bottom wafer and, on the other hand, by the glass wafer 42. The glass wafer 42 can also be arranged on the stack structure 80 by means of a bonding process. Thereby, it can be obtained, for example, that the process chamber does not have to be left for local selective etching and/or for wafer bonding for the encapsulation of the movable element 38, or at least the clean room environment can be maintained without involving any excess effort.

As in other steps of methods described herein, it should be noted that the illustrated order is merely exemplarily and can also be changed. For example, the wafer structure 70 can also be connected to the wafer structure 40 prior to a connection of the structure 40 and 50 and/or the glass wafer can be connected to the wafer structure 50 prior to or after the wafer structure 70 is arranged and/or possibly even prior to the connection of the wafer structures 40 and 50. In particular in a different design of the wafer structures or MEMS, another order of the bonding steps can be advantageous which, however, does not limit the usage of a spacing structure and a glass layer.

The illustrated order of connecting layers or layer sequences is merely exemplary. It is, for example, also possible to connect the glass wafer 42 already prior to bonding the wafer structure 50 or a processed version 50′ thereof, wherein, for example, the layer 12₃ is removed in a local selective manner.

The cavity 44 can be hermetically sealed in the illustrated but also other orders of steps by arranging the functional wafer structure 50 or 50′ and glass wafer 44 in the stack structure by applying a wafer bonding process. On a side of the MEMS structure 46 opposite to the glass wafer 42, for example comprising the movable element 38, by means of a further wafer bonding process, prior or after wafer bonding for connecting the glass wafer, a limiting wafer structure, the layer 12₅, can form part of the stack structure such that the glass wafer 42 on the one side and the limiting wafer structure 12₅ on the other side close the cavity 44 along the stacking direction 36. The functional wafer structure 40/50 and the spacing layer 12₃ can close the cavity 44 perpendicular to the stacking direction 36.

As described in the context of FIG. 7, the limiting wafer structure 12₅ can be structured on a side facing the MEMS structure 46 to comprise a recess in an area opposing the MEMS structure 46. This can, for example, be adapted to a movement of the movable element 38 of the MEMS structure 46.

Here, the recess 37 can be limited by a single or individual semiconductor layer of the limiting wafer structure 70. This means the recess 37 is, for example, produced by a local selective etching method or the same within a single layer, which differs from a multi-layered structure where, for example, wall structures are generated by additional layers. Implementation as a single layer with a recess offers the advantage of a simple and precise definition of the cavity 44.

Glass wafer 42 can be configured in a planar manner completely or at least partly in an area arranged opposite to the MEMS structure 46 or the movable element 38. Irrespective thereof, the spacing can be provided by means of the spacing structure 12₃. Thereby, complex production of a three-dimensional glass body as glass cap can be prevented and still the advantageous of the usage of glass material can be used.

According to an embodiment, the method is performed such that the cavity 44 is hermitically sealed and a pressure differing from an atmosphere pressure or environmental pressure is provided in the cavity. This can simply take place in process chambers for wafer bonding, differing from laboratory tables for classical adhesion of several layers. Embodiments provide that a negative pressure is generated in the cavity. Other embodiments provide that an excess pressure is generated in the cavity, for example a pressure of at least 1.5 bar, 1.8 bar or at least 2 bar or also higher pressures, for example 3 bar. An excess pressure allows decelerating movement of the movable element 38. This is in particular relevant for structures that are operated in a non-resonant manner and allows, for example, reducing or preventing overshoot beyond an intended position.

By adjusting the pressure during joining of layers it is also possible that no getter material is arranged in an area of the cavity. Such a getter material is arranged in known processes to allow pressure adaptation, for example to generate negative pressure at a later point. As this can now already take place during wafer bonding, arranging such a material is still possible but the need therefore is reduced or even prevented.

A movable element 38 is arranged in the stack structure 90. Further, an actuator is provided to deflect the movable element 38 from a resting position which is, for example, also influenced by spring elements or the same. For example, the moveable element 38 includes a mirror structure.

Here, the MEMS structure can be configured such that a control of the moveable element 38 takes place below a mechanical resonant frequency of a spring mass system. The movable element 38 can provide part of a mass of such a spring mass system. A spring suspension can provide a spring part, which both together influence a resonant frequency. While in resonance operated mirrors the springs are suspended in a soft manner to allow resonant operation, a significantly higher spring stiffness is provided in structures for non-resonant operation.

As illustrated, for example, in the context of FIG. 8 and illustrated further in the context of FIG. 9, by means of local selective removal, such as by performing step 330 to remove part of the spacing layer 12₃ after a wafer bonding process has been performed, can be used simultaneously to expose a respective segment of the MEMS structure 46 in order to allow a later movement of the moveable element 38. This can take place by maintaining at least part of the spacing layer 12₃ for example in the external area of the cavity 44, such that the area from which the layer 12₃ is removed is enclosed by the remaining part and at least partly forms the spacing structure. This does not exclude the layer 12₃ being thinned or further structured locally in an external area for adjusting the spacing.

In other words, FIG. 9 shows a schematic illustration for the third wafer bonding, where a lid wafer is combined with the previous wafer stack so that a hermetically encapsulated cavity 44 results in the center. Within this cavity, it is also possible to adjust a defined pressure and/or defined atmosphere composition, such that both negative pressure (technical vacuum), atmosphere, as well as overpressure is possible as work environment for the MEMS component. Overpressure can be used for attenuating post-vibration of a movement of the MEMS component.

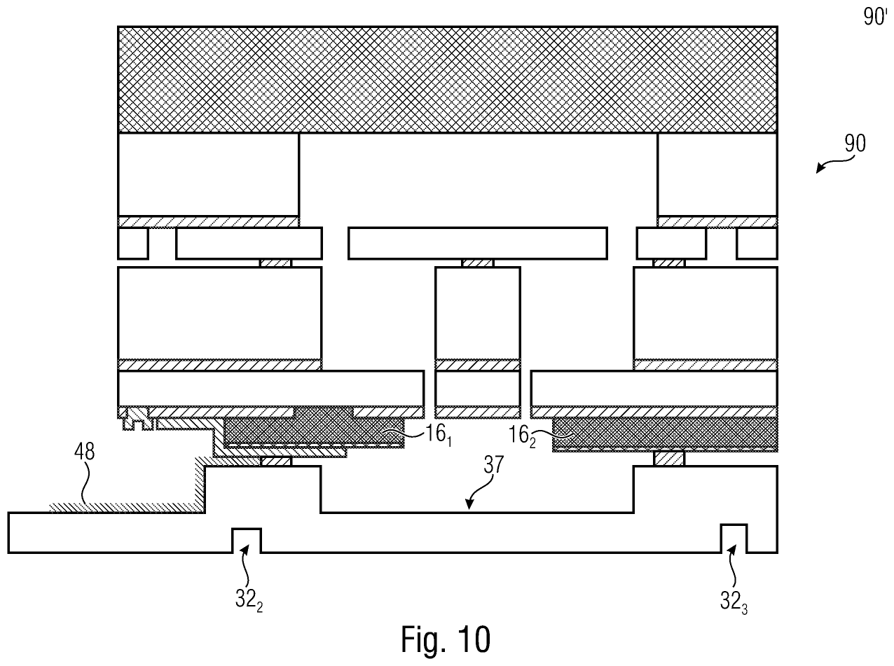

FIG. 10 shows a schematic side sectional view of a stack structure 90′ according to an embodiment that can be obtained by further processing the stack structure 90 of FIG. 9. Thus, for example additional metallization 48 can be provided to electrically contact the actuator structures 16₁ and/or 16₂.

Such steps are optional. According to an embodiment, an inventive method includes dicing the stack structure into a plurality of MEMS packages, such as in an area of the trenches 32₂ and/or 32₃.

Embodiments are directed to providing the spacing layer 12₃ from a semiconductor material, wherein this is not mandatory, even when it results in specific advantages, in particular with regard to MEMS production.

In other words, optionally, a floor wafer can me metallized in order to realize electrical contact to the MEMS component. The glass frit, this means the interface between the spacing structure 12₃ and the glass wafer 42 can be electrically conductive to alternatively or additionally realize electrical contact to the MEMS component.

According to an embodiment, a method includes processing the functional wafer structure 40 and/or 50 in a process chamber and closing the cavity in the process chamber. Embodiments allow a different order of bonding processes, partly also simultaneously, wherein sequential bonding processes can be performed in the same or a different process chamber. Thus, for example the wafer structure 40 of FIG. 4 and the wafer structure 50 of FIG. 5 as well as the structure 70 of FIG. 7 can be prepared and possibly finished structured and the three wafers can be bonded simultaneously in one step, which allows fast processing.

However, it might be simpler or easier to bond the wafer structures 40 and 50 first, then etch or expose the mirror plate and subsequently bond the same with the wafer structure 70. According to an embodiment, which can be performed alternatively or additionally to the method 100, encapsulating an MEMS structure in a stack structure includes providing a stack structure with a plurality of MEMS areas, such that each MEMS area comprises an MEMS structure arranged at least partly in an MEMS cavity, such that the stack structure comprises a spacing structure at least partly enclosing each of the cavities of the MEMS areas and providing a distance to the MEMS structure. Further, a glass wafer, such as the wafer 42, is arranged on the spacing structure by performing a wafer bonding process, such that the cavities on one side of the spacing structure are hermetically sealed by means of the glass wafer. Thus, for example a wafer structure having several usages or layer stacks 18 provided on wafer level can be arranged and the at the same time can be closed at least on one side by the glass wafer 42 by means of wafer bonding.

Although the method described herein is described such that the wafer structure 70 is used to close a side opposite to the glass wafer 42, this is not provided in all embodiments. For example, a continuous substrate layer can be used, which is part of the wafer structure 40 and already provides sealing the cavity on this side. Alternatively or additionally, it is possible to omit the sealing of the cavity on this side or perform the same at a later time.

An MEMS package according to an embodiment, which can be obtained, for example, by dicing the stack structure 90 or 90′, but can also comprise any other MEMS structure, includes a stack structure including several layers stacked along the stacking direction 36 and a functional layer structure including an MEMS structure, for example the MEMS structure 46. Here, the MEMS structure is at least partly arranged in a cavity, such as the cavity 44 comprising the moveable element 38. The cavity is limited along the stacking direction on one side by a glass layer, which is spaced apart from the MEMS structure by a spacing layer along a stacking direction.

Embodiments provide hermetic encapsulation on wafer level, which is advantageous in particular but not exclusively for quasi-static MEMS components, such as MEMS vector scanners, where each resonant behavior is to be prevented. A hermetic encapsulation on wafer level does not only protect the MEMS components from environmental influences such as dust, humidity, vibration and the same from the environment but also allows a defined internal pressure within the encapsulation, such that the behaviors of the MEMS components can be independent of the environmental pressure.

For implementing hermetic encapsulation by wafer bonding, three to four wafers or wafer structures are used in embodiments. The same are discussed in the context of figures described herein. In the embodiments, exemplarily, an MEMS vector scanner is encapsulated, wherein the principle can also be used for other MEMS.

Embodiments can be realized independent of structures, sizes and driving principles. MEMS components can be hermetically encapsulated by the described methods on wafer level in order to protect this MEMS component from the environment, wherein the embodiments are particularly advantageous when using one to two functional wafer structures. In the cavity, not only a negative pressure (technical vacuum, i.e. up to technically realizable low pressures), but also an overpressure can be adjusted. With overpressure, the Q-factor, i.e. the attenuation of the movement of the MEMS component can be lowered, such that the pulse vibration can be significantly attenuated or eliminated.

Embodiments can be applied when producing MEMS components, such as a vector scanner.

Here, embodiments relate to a wafer stack where three to four wafers can be bonded together and that comprises a functional MEMS component as well as a bottom wafer and a lid wafer, such that the MEMS component arranged in the center can operate in a closed cavity at a defined pressure.

According to an embodiment, from the protective function vacuum, atmosphere, but also overpressure as working pressure can be adjusted for the component in the cavity to increase or lower the Q-factors.

According to an embodiment, the bottom wafer can be metallized to realize the electric contact to the MEMS component.

According to an alternative or additional aspect, the glass frit can be electrically conductive to realize the electric contact to the MEMS component.

Although some aspects have been described in the context of an apparatus, it is obvious that these aspects also represent a description of the corresponding method, such that a block or device of an apparatus also corresponds to a respective method step or a feature of a method step. Analogously, aspects described in the context of a method step also represent a description of a corresponding block or detail or feature of a corresponding apparatus.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

### LITERATURE

ADDIN ZOTERO_BIBL {“uncited”:[ ], “omitted”:[ ], “custom”:[ ]} CSL_BIBLIOGRAPHY [1] “Variants of Hermetic Packages for LiDAR Sensors|SCHOTT”. /en-gb/products/hermetic-packages-for-lidar-sensors/product-variants (accessed Sep. 21, 2020).
[2] “Mirrorcle Technologies MEMS Mirrors—Technical Overview”, 2013. https://www.semanticscholar.org/paper/Mirrorcle-Technologies-MEMS-Mirrors-% E2%80%93-Technical/d131a1576787ffa47fbd035881ec3780cf1a09b4 (accessed Sep. 21, 2020).
[3] S. Gu-Stoppel u. a., “AlScN based MEMS quasi-static mirror matrix with large tilting angle and high linearity”, Sens. Actuators Phys., Bd. 312, p. 112107, September 2020, doi: 10.1016/j.sna.2020.112107.

1. Method for encapsulating an MEMS structure in a stack structure, comprising:
providing a functional wafer structure comprising at least partly the MEMS structure;
arranging the functional wafer structure and a glass wafer in the stack structure and along a stacking direction to each other;
such that a cavity in which at least a part of the MEMS structure is arranged is closed on one side along the stacking direction by the glass wafer; and
such that a spacing structure is arranged between the part of the MEMS structure and the glass wafer in the stack structure to provide a spacing between the part of the MEMS structure and the glass wafer along the stacking direction; such that the spacing structure encloses part of the cavity,
wherein the spacing structure is formed of the functional wafer structure by means of local selective removal of the wafer structure.

2. Method according to claim 1, wherein providing the functional wafer structure comprises providing a first functional wafer with a mechanical element and a second functional wafer and the method comprises wafer bonding the first functional wafer and the second functional wafer with one another by means of a wafer bonding process.

3. Method according to claim 1, wherein the cavity is hermetically closed by arranging the functional wafer structure and the glass wafer in the stack structure by using a first wafer bonding process; and by a limiting wafer structure forming part of the stack structure on a side of the MEMS structure opposite to the glass wafer by means of a second wafer bonding process, such that the glass wafer on the one hand and the limiting wafer structure on the other hand close the cavity along the stacking direction; and the functional wafer structure and the spacing structure limit the cavity perpendicular thereto.

4. Method according to claim 3, wherein the limiting wafer structure is structured on a side facing the MEMS structure and comprises a recess in an area opposite to the MEMS structure.

5. Method according to claim 4, wherein the recess is adapted to a movement of a moveable element of the MEMS structure.

6. Method according to claim 4, wherein the recess is limited by a single semiconductor layer of the limiting wafer structure.

7. Method according to claim 3, wherein, opposite to the recess, an indication for subsequent dicing of wafer segments is incorporated in the limiting wafer structure.

8. Method according claim 1, wherein the glass wafer is formed in a planner manner at least in an area that is arranged opposite to the MEMS structure.

9. Method according to claim 1, wherein a side of the glass wafer facing the MEMS structure is formed in a planar manner.

10. Method according to claim 1, which is performed such that the cavity is hermetically closed and a pressure differing from the atmosphere pressure is provided in the cavity.

11. Method according to claim 10, wherein a negative pressure is generated in the cavity.

12. Method according to claim 10, wherein an overpressure is generated in the cavity.

13. Method according to claim 10, wherein no getter material is arranged in an area of the cavity.

14. Method according to claim 1 wherein the MEMS structure comprises a moveable element and an actuator for deflecting the moveable element from a resting position.

15. Method according to claim 14, wherein the moveable element comprises a mirror structure.

16. Method according to claim 14, wherein the MEMS structure is configured such that a control of the moveable element takes place below a mechanical resonant frequency of a spring-mass system, wherein the moveable element provides at least a part of a mass of the spring-mass system.

17. Method according to claim 1, further comprising:
locally selectively removing a spacing layer after the wafer bonding process in a first area to expose the functional wafer structure at least partly while maintaining at least a part of the spacing layer in a second area enclosing the first area to at least partly form the spacing structure.

18. Method according to claim 1, wherein providing the functional wafer structure comprises:
providing a first functional wafer comprising a first segment of a moveable element of the MEMS structure; and a second functional wafer comprising a second segment of the moveable element of the MEMS structure and at least a spacing layer that at least partly forms a stack together with the second segment;
wafer bonding of the first functional wafer and the second functional wafer with one another by means of a wafer bonding process; such that the first segment and the second segment are connected to one another, to at least partly form the moveable element;
wherein the method further comprises:
locally selectively removing the spacing layer after the wafer bonding process in a first area of the second segment to expose the second segment while maintaining at least of the spacing layer in a second area enclosing the first area to at least partly form the spacing structure.

19. Method according to claim 1, further comprising:
dicing the stack structure into a plurality of MEMS packages.

20. Method according to claim 1, wherein the spacing structure comprises a semiconductor material.

21. Method according to claim 1, further comprising:
processing the functional wafer structure in a process chamber;
closing the cavity in the same process chamber or a different process chamber.

22. Method for encapsulating an MEMS structure in a stack structure, comprising:
providing a stack structure with a plurality of MEMS areas, such that each MEMS area comprises an MEMS structure that is arranged at least partly in an MEMS cavity; such that the stack structure comprises a spacing structure enclosing each of the cavities of the MEMS areas at least partly and providing a spacing to the MEMS structure along a stacking direction, wherein the spacing structure is formed from the functional wafer structure by means of local selective removal of the wafer structure; and
arranging a glass wafer on the spacing structure along the stacking direction by performing a wafer bonding process, such that the cavities on one side of the spacing structure are hermetically sealed by means of the glass wafer.

23. MEMS package, comprising:
a stack structure comprising several layers stacked along a stacking direction; and comprising a functional layer structure comprising an MEMS structure;
wherein the MEMS structure is at least partly arranged in a cavity; and the cavity forms part of the stack structure;
wherein the cavity is limited on one side along the stacking direction by a glass layer, which is spaced apart from the MEMS structure along the stacking direction by a spacing layer, wherein the spacing structure is formed from the functional wafer structure by means of local selective removal of the wafer structure.
